(19) United States
(12) Patent Application Publication
(10) Pub. No.: US 2009/0250721 A1
(43) Pub. Date: Oct. 8, 2009

(54) ELECTRICAL SURGE PROTECTIVE APPARATUS

(75) Inventors: Tsutomu SONE, Kanagawa (JP); Osamu OONISHI, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/418,041

(22) Filed: Apr. 3, 2009

(30) Foreign Application Priority Data
Apr. 3, 2008 (JP) 2008-097152

(51) Int. Cl. H01L 23/62

(52) U.S. Cl. 257/173; 257/E23.141; 257/565

(57) ABSTRACT

Disclosed is an electrical surge protective apparatus comprising: a base region containing impurities of a first conductivity type; a first semiconductor region containing impurities of a second conductivity type; a second semiconductor region containing impurities of the same conductivity type as that of the second conductivity type; and a high resistance region having a lower impurity concentration than the second semiconductor region. The first semiconductor region is joined to the base region on its upper surface side. The second semiconductor region is joined to the base region on its lower surface side. The high resistance region is electrically connected to both the base region and the second semiconductor region.

This application is based on Japanese Patent Application No. 2008-097152 which is herein incorporated by reference.

### BACKGROUND

1. Technical Field

The present invention relates to an electrical surge protective apparatus for protecting an electrical circuit from a surge voltage or an abnormal voltage.

2. Related Art

Surge protective devices, such as barristers and constant-voltage diodes (i.e., Zener diodes), have been widely used in order to protect an electrical circuit from a surge voltage (an excessive voltage exceeding a withstand voltage level of the circuit) and from an abnormal voltage (e.g., noise that causes an error in an operation of the circuit). In particular, recent semiconductor devices are easily affected by the surge voltage and the abnormal voltage, due to the high integration and high-density packaging of semiconductor devices. A typical electrical surge protective device is in an electrically insulating state when a normal voltage is applied to the electrical circuit, and have capability for absorbing the current induced by an excessive voltage when an excessive voltage is applied to the electrical circuit. Prior art documents related to such an electrical surge protective device are, for example, Japanese patent application publication Nos. 2003-110119, 2003-110120, and 2006-269790.

An electrical surge protective device disclosed in Japanese patent application publication No. 2003-110119 has an npn-type bipolar transistor structure in which a base region is in an electrically floating state. This structure allows fluctuation in the breakdown voltage of the electrical surge protective device depending on ambient temperature and surrounding environment (e.g., an environment where a noise source is located in the vicinity of electrical surge protective device). The fluctuation can induce fluctuation in the voltage of the base region, thereby causing malfunction of the electrical surge protective device at an unexpected timing. In addition, the typical electrical surge protective device is sealed with resin that forms a protective film. However, residual stress can be generated on the surface of the electrical surge protective device sealed with the resin, thereby causing fluctuation in the breakdown voltage of the typical electrical surge protective device. Furthermore, the breakdown voltage of the typical electrical surge protective device can fluctuate due to external factors such as adhesion of movable ions in the resin, change in the temperature or humidity, metal pollution, impact or vibration.

### SUMMARY

In accordance with one aspect of the present Invention, there is provided an electrical surge protective apparatus which comprises: a base region containing impurities of a first conductivity type; a first semiconductor region joined to the base region on an upper surface side thereof and containing impurities of a second conductivity type that is different from the first conductivity type; a second semiconductor region joined to the base region on a lower surface side thereof and containing impurities of the same conductivity type as that of the second conductivity type; a high resistance region electrically connected to both the base region and the second semiconductor region, the high resistance region containing impurities of the same conductivity type as that of the second conductivity type and having a lower impurity concentration than the second semiconductor region; a first electrode terminal electrically connected to the first semiconductor region; and a second electrode terminal electrically connected to the second semiconductor region.

Further features of the invention, its nature and various advantages will be more apparent from the accompanying drawings and the following detailed description of various embodiments.

### BRIEF DESCRIPTION OF THE DRAWINGS

The above and other objects, advantages and features of the present invention will be more apparent from the following description of certain preferred embodiments, taken in conjunction with the accompanying drawings, in which:

FIG. 1 is a schematic cross sectional diagram showing the structure of the electrical surge protective apparatus according to a first embodiment of the present invention;

FIG. 2 is a diagram showing an equivalent circuit of the electrical surge protective apparatus according to the first embodiment;

FIG. 3 is a graph schematically showing part of the current-voltage properties of a bidirectional diode;

FIG. 4 is a schematic cross sectional diagram showing the structure of the electrical surge protective apparatus according to a second embodiment of the present invention;

FIG. 5 is a diagram showing an equivalent circuit of the electrical surge protective apparatus according to the second embodiment; and

FIG. 6 is a schematic cross sectional diagram showing the structure of the electrical surge protective apparatus according to a third embodiment of the present invention.

### DETAILED DESCRIPTION

The invention will now be described herein with reference to illustrative embodiments. Those skilled in the art will recognize that various alternative embodiments can be accomplished using teachings of the present invention, and that the present invention is not limited to exemplary embodiments illustrated for explanatory purposes.

It is understood that identical elements in the different figures are referred to by the same reference numeral, and its detailed description will not be repeated.

### First Embodiment

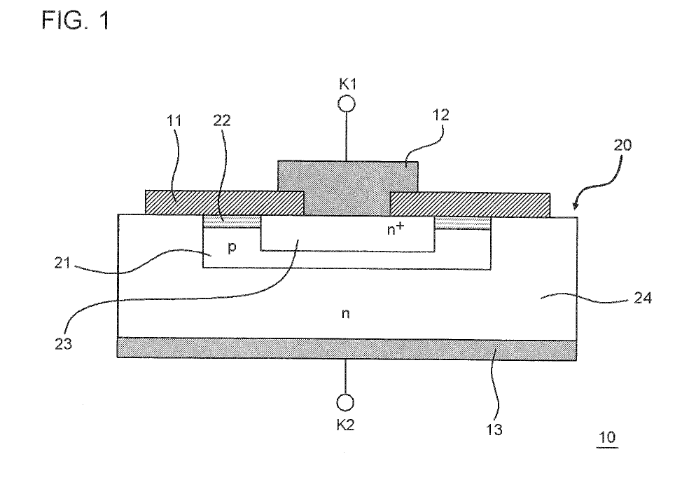

FIG. 1 is a schematic cross sectional diagram showing the structure of the electrical surge protective apparatus 10 according to a first embodiment of the present invention. As shown in FIG. 1, the electrical surge protective apparatus 10 according to the present invention has a base region (p-type diffusion region) 21 containing impurities of a first conductivity type (p-type), a first semiconductor region (n⁺-type diffusion region) 23 containing impurities of a second conductivity type that is different from the first conductivity type (n⁺-type), a second semiconductor region (n-type diffusion region) 24 containing impurities of the same conductivity type as the second conductivity type (n-type), and a high resistance region 22 containing impurities of the same conductivity type as the second conductivity type (n⁻-type). The base region 21 is joined to the first semiconductor region 23 on the upper surface side, as well as to the second semiconductor region 24 on the lower surface side.

The high resistance region 22 is electrically connected to all of the base region 21, the first semiconductor region 23 and the second semiconductor region 24, contains impurities of the same conductivity type as the second conductivity type (n⁺-type), and has a lower impurity concentration than the second semiconductor region 24. The electrical surge protective apparatus 10 has a first electrode terminal 12 electrically connected to the first semiconductor region 23, and a second electrode terminal 13 electrically connected to the second semiconductor region 24.

The n⁺-type diffusion region 23, the base region 21 and the n-type diffusion region 24 are formed in the silicon substrate 20 in this order in the depth direction of the silicon substrate 20. The base region 21 is surrounded by the n-type diffusion region 24 and the n⁺-type diffusion region 23 is surrounded by this base region 21 so as to be separated from the n-type diffusion region 24. The shape of the base region 21 as viewed from the top may be a hollow quadrilateral, a hollow polygon or a ring, for example. The shape of the n⁺-type diffusion region 23 as viewed from the top may be a quadrilateral, a polygon or a circle, for example.

It is desirable for the thickness of the base region 21 (that is, the distance between the n-type diffusion region 24 and the n⁺-type diffusion region 23) to be uniform throughout the entirety, from the point of view of stability in the properties of the electrical surge protective apparatus 10.

In addition, though the high resistance region 22 is formed so as to be electrically connected to all of the regions: the base region 21, the n⁺-type diffusion region 23 and the n-type diffusion region 24, the invention is not limited to this. As described below, a configuration where the high resistance region 22 is connected to both the base region 21 and the n-type diffusion region 24 without being connected to the n⁺-type diffusion region 23 is also possible. The n⁻-type high resistance region 22 is joined to the upper portion of the base region 21, and formed in the region surrounded by an insulating film 11, the n-type diffusion region 24 and the n⁺-type diffusion region 23. The shape of this base region 21 as viewed from the top may be a hollow quadrilateral, a hollow polygon or a ring, for example. The n⁺-type diffusion region 23 is connected to a first external terminal K1 via a first electrode terminal (first cathode electrode) 12, and the second semiconductor region 24 is connected to a second external terminal K2 via a second electrode terminal (second cathode electrode) 13.

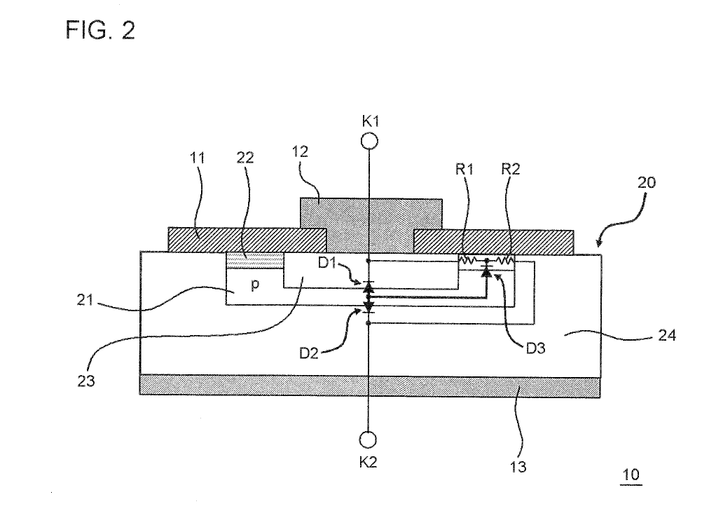

The n⁺-type diffusion region 23, the base region 21 and the n-type diffusion region 24 are connected in series, and thus form an npn-type bipolar transistor structure. FIG. 2 is a diagram showing an equivalent circuit of the electrical surge protective apparatus 10 in FIG. 1. This equivalent circuit includes two diode elements D1 and D2, two resistor elements R1 and R2, and a parasitic diode D3. One diode element D1 is formed of a pn junction between the p-type diffusion region 21 and the n⁺-type diffusion region 23, and the other diode element D2 is formed of a pn junction between the p-type diffusion region 21 and the n-type diffusion region 24. Thus, the diode elements D1 and D2 form a so-called bidirectional diode. In addition, the parasitic diode D3 is formed of a pn junction between the p-type diffusion region 21 and the high resistance region 22. As shown in FIG. 2, the anode of this parasitic diode D3 is connected to the anode of the diode element D1 and the anode of the diode element D2.

As shown in the equivalent circuit in FIG. 2, a resistor element R1 is formed between the cathode of the diode element D1 and the cathode of the parasitic diode D3. A resistor element R2 is also formed between the cathode of the diode element D2 and the cathode of the parasitic diode D3. The resistor element R1 corresponds to a portion of the high resistance region 22 which electrically connects the p-type diffusion region 21 and the n⁺-type diffusion region 23. The resistor element R2 corresponds to a portion of the high resistance region 22 which electrically connects the p-type diffusion region 21 and the n-type diffusion region 24. In addition, the potential between the diode elements D1 and D2 corresponds to the potential V_{B} of the base region 21.

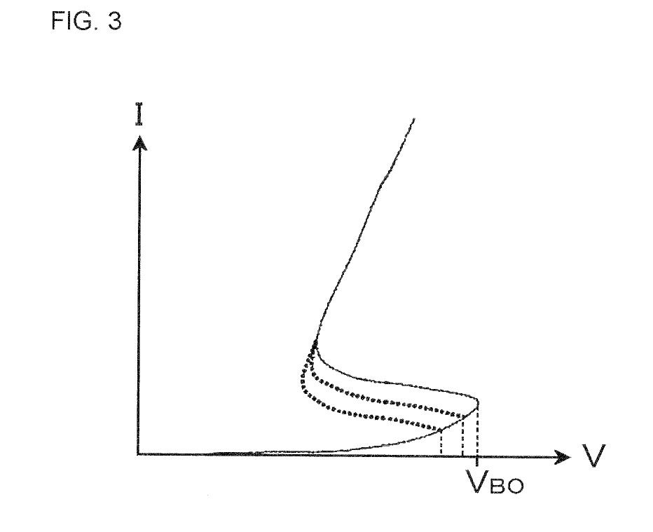

A microscopic current can flow through the high resistance region 22, and therefore, it is possible to prevent the potential V_{B} of the base region 21 from fluctuating. FIG. 3 is a graph schematically showing part of the current-voltage properties (I-V properties) of the bidirectional diode in the case where a constant reference potential (ground potential) is applied to the second external terminal K2 and a positive voltage is applied to the first external terminal K1. When an excessive voltage exceeding the breakdown voltage V_{BO} is applied to the first external terminal K1, the diode element D1 breaks down. As a result, the electrical surge protective apparatus 10 operates so that a sudden, strong current flows between the first external terminal K1 and the second external terminal K2. As shown by the solid line in the graph, the breakdown voltage V_{BO} remains approximately constant and is stable, irrespectively of the ambient environment. In the case where there is no high resistance region 22, the breakdown voltage V_{BO} fluctuates, as shown by the broken line in FIG. 3, and therefore, there is a risk that the electrical surge protective apparatus 10 may malfunction with unexpected timing.

The n⁺-type diffusion region 23, base region 21 and n type diffusion region 24 are formed within the same silicon substrate 20 in this order in the depth direction of the silicon substrate 20. The p-type diffusion region 21 is formed through ion injection, for example, by selectively introducing p-type impurities, such as boron, into a silicon substrate 20 containing n-type impurities, using a mask. In the case where the p-type diffusion region 21 is formed through ion injection, boron ions may be implanted using a beam energy of approximately 50 KeV, with a dose amount of approximately 1×10¹³ cm⁻² (atoms/cm cm²) to 1×10¹⁴ cm⁻² (atoms/cm²), for example. As described above, n-type impurities, such as phosphorus or arsenic, are selectively introduced in a relatively shallow region in the silicon substrate 20, where the p-type diffusion region is formed, in accordance with a diffusion method, under such conditions that the temperature is approximately 1000° C., for example, and thus, a high concentration n⁺-type diffusion region 23 is formed. As a result, the p-type diffusion region 21 is surrounded by the n-type diffusion region 24 in the vicinity of one main surface of the silicon substrate 20, and the n⁺-type diffusion region 23 is surrounded by the p-type diffusion region 21.

The high resistance region 22 is formed in the vicinity of the surface above the outer portion (ring portion) of the p-type base region 21, by introducing n-type impurities, such as phosphorus, through ion implantation in the entirety of the surface of the silicon substrate 20, or in part, using a mask, for example. A high resistance region 22 having approximately 1 MΩ to several MΩ may be formed. In the case where the high resistance region 22 is formed through ion implantation, phosphorous ions may be implanted with a beam energy of approximately 50 KeV, with a dose amount of approximately 1×10¹³ cm⁻² (atoms/cm²). It is preferable for the impurity concentration of the n⁻-type high resistance region 22 to be sufficiently lower than that of the n⁺-type diffusion region 23 and the n-type diffusion region 24, from the point of view of stability in the base potential V_{B}. When the impurity concentration of the n⁺-type diffusion region 23 is within a range of 1×10⁷ cm⁻³ to 1×10²⁰ cm⁻³ and the impurity concentration of the p-type base region 21 is within a range of 1×10¹⁴ cm⁻³ to 1×10¹⁵ cm⁻³ for example, it is desirable for the impurity concentration of the n⁻-type high resistance region 22 to be within a range of 1×10¹² cm⁻³ to 1×10¹⁴ cm⁻³.

The insulating film 11, for example the silicon oxide film, is formed and patterned on top of the high resistance region 22. The insulating film 11 has an opening through which the n⁺-type diffusion region 23 is exposed from the surface of the silicon substrate 20. In this opening, the first cathode electrode 12 made of a metal, such as aluminum, is provided so as to make electrical contact with the n⁺-type diffusion region 23. Meanwhile, a second cathode electrode 13 made of a metal is provided on the rear side of the silicon substrate 20 so as to make electrical contact with the n-type diffusion region 24.

The effects of the electrical surge protective apparatus 10 according to the first embodiment are described below.

The electrical surge protective apparatus 10 is sealed in a resin (not shown) that forms a protective film. When this resin includes movable ions, such as of a metal, or movable ions enter from the outside, the movable ions may move so as to reach the base region 21. The movable ions may move along the interface between the insulating film 11 and the silicon substrate 20 or enter into the n⁺-type diffusion region 23 so as to reach the base region 21, depending on the voltage applied across the first external terminal K1 and the second external terminal K2, and thus, the potential of the base region 21 may become unstable. In the case where the base region 21 is in an electrically floating state, the potential of the base region 21 may become unstable, due to residual stress from the resin for sealing the electrical surge protective apparatus or external factors, such as change in temperature or moisture, or impact The fluctuation in the potential of the base region 21 easily leads to fluctuation in the breakdown voltage V_{BO}, as shown by the dotted line in FIG. 3.

Meanwhile, in the electrical surge protective apparatus 10 of the present embodiment, the high resistance region 22 forms a current path (resistor element R1 and resistor element R2 in FIG. 2) between the n⁺-type diffusion region 23 and the n-type diffusion region 24. In addition, there is a pn junction between the base region 21 and the high resistance region 22, and thus, a parasitic diode D3 is formed. That is to say, the parasitic diode D3 is a diode formed between the base region 21 having a low concentration (for example 1×10¹⁴ cm⁻³ to 1×10¹⁵ cm⁻³) and the n⁻-type high resistance region 22 having a low concentration (for example 1×10¹² cm⁻³ to 1×10¹⁴ cm³), and therefore, the drop in voltage (Vf) of the parasitic diode D3 in the forward direction is smaller than the drop in voltage (Vf) of the diode element D2 in the forward direction, and as a result, a leak current (microscopic current) easily flows through the parasitic diode D3.

Accordingly, a leak current flows through the high resistance region 22 in the electrical surge protective apparatus 10, and thus, the potential of the base region 21 can be prevented from fluctuating. Thus, the breakdown voltage V_{BO} of the bidirectional diode made up of the diode elements D1 and D2 is stable, and it becomes possible to prevent the electrical surge protective apparatus 10 from malfunctioning.

### Second Embodiment

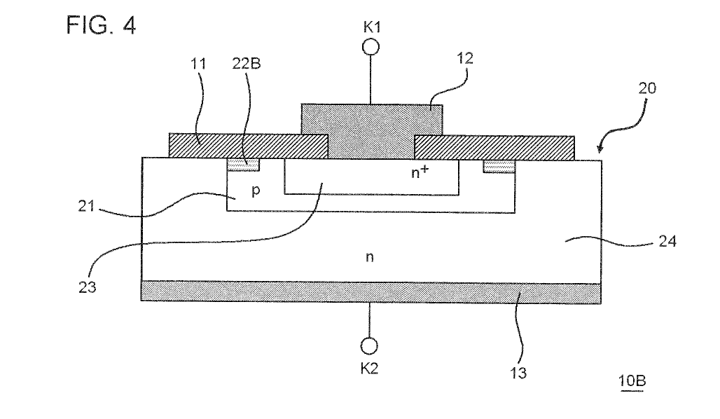

Next, the second embodiment of the present invention is described. FIG. 4 is a schematic cross sectional diagram showing the structure of the electrical surge protective apparatus 10B according to the second embodiment. The electrical surge protective apparatus 10B in FIG. 4 has the same structure as the electrical surge protective apparatus 10 (FIG. 1), except that the high resistance region 22B is not connected to the n⁺-type diffusion region 23 but electrically connected to both the p-type diffusion region 21 and the n-type diffusion region 24.

The high resistance region 22B is formed in the vicinity of the surface above the outer portion (ring portion) of the p-type base region 21 by selectively introducing n-type impurities, such as phosphorus, in the silicon substrate 20 through ion implantation using a mask, for example. A high resistance region 22B having approximately 1 MΩ to several MΩ may be formed. The concrete manufacturing process and conditions, such as the concentration, of the high resistance region 22B are the same as that for the high resistance region 22 according to the first embodiment.

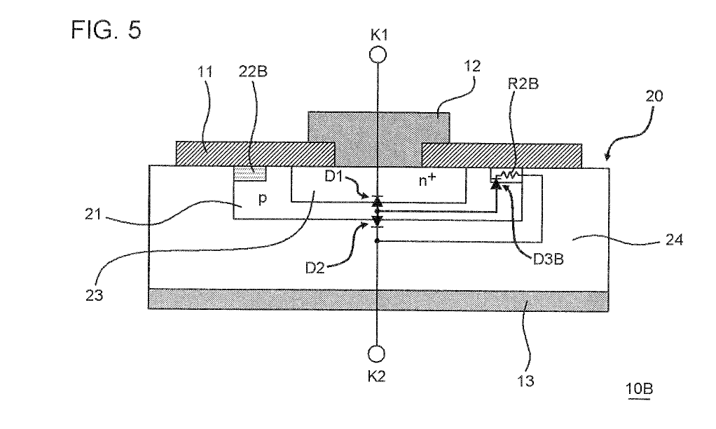

FIG. 5 is a diagram showing an equivalent circuit of the electrical surge protective apparatus 10B in FIG. 4. This equivalent circuit includes diode elements D1 and D2 that form a bidirectional diode, a resistor element R2B and a parasitic diode D3B. The parasitic diode D3B is formed of a pn junction between the p-type diffusion region 21 and the high resistance region 22B. The anode of this parasitic diode D3B is connected to the anode of the diode element D1 and the anode of the diode element D2. The high resistance region 22B is not connected to the n⁺-type diffusion region 23, and therefore, the equivalent circuit in FIG. 5 does not have the resistor element R1 in FIG. 2.

A microscopic current can also flow through the high resistance region 22B in the electrical surge protective apparatus 10B according to the present embodiment, and therefore, the potential of the base region 21 can be prevented from fluctuating, and thus, the breakdown voltage of the bidirectional diode made up of the diode elements D1 and D2 is stable. That is to say, there is a pn junction between the base region 21 and the high resistance region 22B, so that the parasitic diode D3B is formed. The high resistance region 22B forms a current path (resistor element R2B in FIG. 5) between the base region 21 and the n-type diffusion region 24 via the parasitic diode D3B. This parasitic diode D3B is a diode formed between the base region 21 having a low concentration (for example 1×10¹⁴ cm⁻³ to 1×10¹⁵ Cm⁻³) and then-type high resistance region 22B having a low concentration (for example 1×10¹² cm⁻³ to 1×10¹⁴ cm⁻³), and therefore, the drop in voltage (Vf) of the parasitic diode D3B in the forward direction is smaller than the drop in voltage (Vf) of the diode element D2 in the forward direction, and as a result, a leak current (microscopic current) easily flows through the parasitic diode D3. Accordingly, in the electrical surge protective apparatus 10B, a leak current flows through the high resistance region 22B, and thus, the potential of the base region 21 can be prevented from fluctuating. Therefore, the breakdown voltage V_{BO} of the bidirectional diode made up of the diode elements D1 and D2 is stable, and it becomes possible to prevent the electrical surge protective apparatus 10B from malfunctioning.

### Third Embodiment

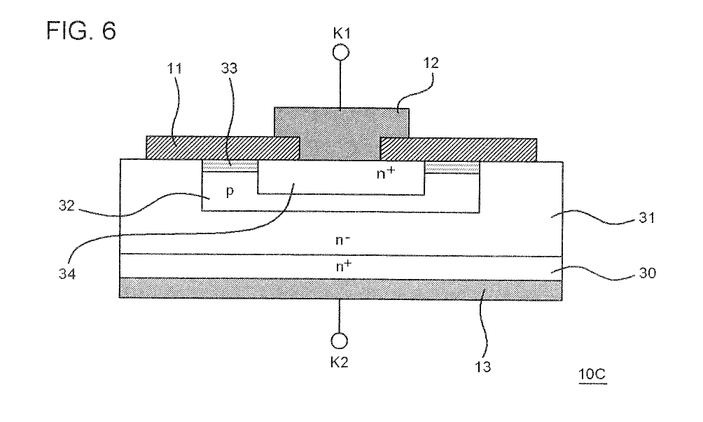

Next, the third embodiment of the present invention is described. FIG. 6 is a schematic cross sectional diagram showing the structure of the electrical surge protective apparatus 10C according to the third embodiment.

As shown in FIG. 6, the electrical surge protective apparatus 10C has a base region (p-type diffusion region) 32 containing impurities of a first conductivity type (p-type), a first semiconductor region (n⁺-type diffusion region) 34 containing impurities of a second conductivity type which is different from the first conductivity type (n⁺-type), a second semiconductor region (n⁻-type diffusion region) 31 containing impurities of the same conductivity -type as the second conductivity type (n⁻-type), and a high resistance region 33 containing impurities of the same conductivity type as the second conductivity type (n⁻-type). The base region 32 is joined to the first semiconductor region 34 on the upper surface side, as well as to the second semiconductor region 31 on the lower surface side.

The layer formed of the n⁻-type diffusion region 31 is an epitaxial layer formed on one main surface of the n⁺-type silicon substrate 30 in accordance with an epitaxial growth method. The p-type diffusion region 32, the high resistance region 33 and the n⁺-type diffusion region 34 are formed within this epitaxial layer The n⁺-type diffusion region 34, the p-type base region 32 and the n⁻-type diffusion region 31 are formed within this epitaxial layer in this order in the depth direction of the epitaxial layer. The n⁺-type diffusion region 34 is formed so as to be surrounded by part of the base region 32 in the vicinity of one main surface of the epitaxial layer, and the part of the base region 32 surrounding the n⁺-type diffusion region 34 is formed so as to be surrounded by part of the n⁻-type diffusion region 31 in the vicinity of the main surface of the epitaxial layer. The high resistance region 33 is joined to a portion of the base region 32 in the vicinity of one main surface of the epitaxial layer, and formed between the n⁺-type diffusion region 34 and the n⁻-type diffusion region 31.

Though the high resistance region 33 is formed so as to be electrically connected to all of the regions: the base region 32, the n⁺-type diffusion region 34 and the n⁻-type diffusion region 31, the invention is not limited to this, and the high resistance region 33 may be connected to both the base region 32 and the n⁻-type diffusion region 31 without being connected to the n⁺-type diffusion region 34.

The p-type diffusion region (base region) 32 can be formed by selectively introducing p-type impurities, such as boron, in the vicinity of one main surface of the epitaxial layer through ion implantation, for example. The n⁺-type diffusion region 34 having a high concentration can be formed in a relatively shallow region of the epitaxial layer, where a p-type diffusion region is formed as described above, by selectively introducing n-type impurities, such as phosphorus or arsenic, in accordance with a diffusion method using a mask, for example. As a result, the base region 32 is surrounded by the n⁻-type diffusion region 31 in the vicinity of one main surface of the epitaxial layer, and the n⁺-type diffusion region 34 is surrounded by the base region 32.

The high resistance region 33 is formed in the vicinity of the surface above the outer portion (ring portion) of the base region 32 by introducing n-type impurities, such as phosphorus, through ion implantation in the entirety of the surface of the epitaxial layer, or in part, using a mask, for example.

A high resistance region 33 having approximately 1 MΩ to several MΩ may be formed in the same manner as with the high resistance region 22 according to the first embodiment (FIG. 1).

The n⁺-type diffusion region 34 is connected to the first external terminal K1 in the opening of the insulating film 11 via the first electrode terminal (first cathode electrode) 12. The n⁻-type diffusion region 31 is connected to the second external terminal K2 via the n⁺-type silicon substrate 30 and the second electrode terminal (second cathode electrode) 13.

In the above described configuration, the n⁺-type diffusion region 34, the p-type base region 32 and the n⁻-type diffusion region 31 are connected in series in the depth direction of the epitaxial layer, and as a result, an npn-type bipolar transistor structure is formed. Accordingly, the electrical surge protective apparatus 10C according to the third embodiment has substantially the same equivalent circuit as that shown in FIG. 2.

Accordingly, a microscopic current flows through the high resistance region 33 connected to the base region 32 in FIG. 6, and thus, it becomes possible to prevent the potential of the base region 32 from fluctuating. Thus, the breakdown voltage of the electrical surge protective apparatus 10C is stable, and it becomes possible to prevent the electrical surge protective apparatus 10C from malfunctioning.

Furthermore, the n⁻-type diffusion region 31 is formed in accordance with an epitaxial growth method, and therefore, the impurity concentration of the n⁻-type diffusion region 31 can be made lower than that of the n⁺-type diffusion region 34 by one digit or more, for example. Therefore, the width of the depletion layer resulting from the pn junction between the p-type diffusion region 32 and the n⁻-type diffusion region 31 can be made greater than the width of the depletion layer resulting from the pn junction between the p-type diffusion region 32 and the n⁺-type diffusion region 34. Accordingly, the parasitic capacitance resulting from the pn junction between the p-type diffusion region 32 and the n⁻-type diffusion region 31 can be made half or less of the parasitic capacitance resulting from the pn junction between the p-type diffusion region 32 and the n⁺-type diffusion region 34. When the capacitance of the electrical surge protective apparatus connected to an electrical circuit is great, the input signal in the electric circuit is attenuated, or the quality of the signal deteriorates, and therefore, it is desirable for the capacitance of the electrical surge protective apparatus to be low. From this point of view, it is possible for the electrical surge protective apparatus 10C according to the third embodiment to have a lower capacitance than the electrical surge protective apparatus 10 in FIG. 1.

Though embodiments of the present invention are described above with reference to the drawings, these are mere examples of the present invention, and various configurations other than the above can be adopted. For example, though the high resistance region 33 is formed so as to be electrically connected to all of the regions: the base region 32, the n⁺-type diffusion region 34 and the n⁻-type diffusion region 31, according to the third embodiment, the invention is not limited to this. As in the second embodiment, the high resistance region 33 may be connected to both the base region 32 and the n⁻-type diffusion region 31 without being connected to the n⁺-type diffusion region 34.

It is understood that the foregoing description and accompanying drawings set forth the above embodiments of the present invention at the present time. Various modifications, additions and alternatives will, of course, become apparent to those skilled in the art in light of the foregoing teachings without departing from the spirit and scope of the disclosed invention. Thus, it should be appreciated that the invention is not limited to the disclosed embodiments, but may be practiced within the full scope of the appended claims.

It is apparent that the present invention is not limited to the above embodiment, and may be modified and changed without departing from the scope and spirit of the invention.

What is claimed is:

1. An electrical surge protective apparatus comprising:
a base region containing impurities of a first conductivity type;
a first semiconductor region joined to said base region on an upper surface side thereof and containing impurities of a second conductivity type that is different from said first conductivity type;
a second semiconductor region joined to said base region on a lower surface side thereof and containing impurities of a same conductivity type as that of said second conductivity type;
a high resistance region electrically connected to both said base region and said second semiconductor region, said high resistance region containing impurities of a same conductivity type as that of said second conductivity type and having a lower impurity concentration than said second semiconductor region;
a first electrode terminal electrically connected to said first semiconductor region; and
a second electrode terminal electrically connected to said second semiconductor region.

2. The electrical surge protective apparatus according to claim 1, wherein said high resistance region is electrically connected to all of said base region, said second semiconductor region and said first semiconductor region.

3. The electrical surge protective apparatus according to claim 1, wherein said first semiconductor region, said base region and said second semiconductor region are connected in series thereby to have a bipolar transistor structure.

4. The electrical surge protective apparatus according to claim 3, wherein:
said first semiconductor region, said base region and said second semiconductor region in this order are formed within a semiconductor substrate in a depth direction of said semiconductor substrate;
said first semiconductor region is formed so as to be surrounded by a part of said base region in the vicinity of a main surface of said semiconductor substrate;
said part of said base region surrounding said first semiconductor region is formed so as to be surrounded by a part of said second semiconductor region in the vicinity of the main surface of said semiconductor substrate; and
said high resistance region is joined to said part of said base region and formed between said first semiconductor region and said second semiconductor region.

5. The electrical surge protective apparatus according to claim 3, further comprising a semiconductor substrate disposed between said second electrode terminal and said second semiconductor region, and containing impurities of a same conductivity type as that of said second conductivity type,
wherein said second semiconductor region is formed within an epitaxial layer that is epitaxially grown on said semiconductor substrate.

6. The electrical surge protective apparatus according to claim 5, wherein:
said first semiconductor region, said base region and said second semiconductor region in this order are formed within said epitaxial layer in a depth direction of said epitaxial layer;
said first semiconductor region is formed so as to be surrounded by a part of said base region in the vicinity of a main surface of said epitaxial layer;
said part of said base region is formed so as to be surrounded by a part of said second semiconductor region in the vicinity of the main surface of said epitaxial layer; and
said high resistance region is joined to said part of said base region in the vicinity of the main surface of said epitaxial layer, and formed between said first semiconductor region and said second semiconductor region.
